(19) United States
(12) Patent Application Publication
(10) Pub. No.: US 2025/0391473 A1
(43) Pub. Date: Dec. 25, 2025

(54) NONVOLATILE MEMORY DEVICE HAVING HIGH BANDWIDTH INPUT/OUTPUT PADS

(71) Applicant: SAMSUNG ELECTRONICS CO., LTD., SUWON-SI (KR)

(72) Inventors: MINSU KIM, SUWON-SI (KR); HONGSOO JEON, SUWON-SI (KR)

(21) Appl. No.: 19/071,112

(22) Filed: Mar. 5, 2025

(30) Foreign Application Priority Data
Jun. 19, 2024 (KR) 10-2024-0079649

(51) Int. Cl. G11C 16/08; G11C 16/10; G11C 16/32

(52) U.S. Cl. CPC G11C 16/08; G11C 16/102; G11C 16/32

(57) ABSTRACT

A non-volatile memory device includes a cell array having a first memory area and a second memory area, a first page buffer circuit configured to write first data into the first memory area or sense the first data stored in the first memory area, a second page buffer circuit configured to write second data into the second memory area or sense the second data stored in the second memory area, a first data pad set disposed on a first side surface of the cell array and electrically connected to the first page buffer circuit, and a second data pad set disposed on a second side surface of the cell array and electrically connected to the second page buffer circuit. The first data pad set and the second data pad set are electrically separated from each other.

### CROSS-REFERENCE TO RELATED APPLICATIONS

This U.S. patent application claims priority under 35 U.S.C. § 119 to Korean Patent Application No. 10-2024-0079649 filed on Jun. 19, 2024, in the Korean Intellectual Property Office, the disclosure of which is incorporated by reference in its entirety herein.

### 1. TECHNICAL FIELD

Embodiments of the present disclosure described herein are directed to a semiconductor memory device, and more specifically to a non-volatile memory device having a high-bandwidth input/output pad.

Semiconductor memory devices can be broadly divided into volatile memory and non-volatile memory. Volatile memory, such as Dynamic Random-Access-Memory (DRAM) or Static Random-Access-Memory (SRAM) have fast reading and writing speeds, but stored data is lost when a power supply is cut off. On the other hand, non-volatile memory can retain stored data even if the power supply is interrupted. Flash memory is an example of non-volatile memory that is typically used in portable storage devices, solid-state drives (SSDs), Smartphones, tablets, and cameras.

Meanwhile, as technology advances, the data input/output speed of flash memory is increasing. A chip housing flash memory (e.g., a flash memory chip) receives data through input pads and outputs data through output pads. A set of input/output pads is typically disposed on one side of the flash memory chip. Through this set of input/output pads, write data may be input from the outside to a page buffer within the flash memory chip. Read data latched in the page buffer may be output to an external device through a data path circuit and the input/output pad set. However, it is difficult to accommodate high bandwidth data input/output requirements with the current input/output pad set.

### SUMMARY

Embodiments of the present disclosure provide a non-volatile memory device having a high-bandwidth input/output pad capable of high-speed data input/output.

According to an embodiment of the inventive concept, a non-volatile memory device includes a cell array having a first memory area and a second memory area, a first page buffer circuit, a second page buffer circuit, a first data pad set, and a second data pad set. The first buffer circuit is configured to write first data into the first memory area or sense the first data stored in the first memory area. The second page buffer circuit is configured to write second data into the second memory area or sense the second data stored in the second memory area. The first data pad set is disposed on a first side surface of the cell array and electrically connected to the first page buffer circuit. The second data pad set is disposed on a second side surface of the cell array and electrically connected to the second page buffer circuit. The first data pad set and the second data pad set are electrically separated from each other.

According to an embodiment of the inventive concept, a non-volatile memory device includes a cell array having first to fourth memory areas, first to fourth page buffer circuits respectively performing data input/output of the first to fourth memory areas, a first data pad set, a second data pad set, a first data path circuit and a second data path circuit. The first data pad set is disposed on a first side surface of the cell array and electrically connected to the first page buffer circuit or the second page buffer circuit. The second data pad set is disposed on a second side surface of the cell array and electrically connected to the third page buffer circuit or the fourth page buffer circuit. The first data path circuit is configured to transfer data between the first page buffer circuit or the second page buffer circuit and the first set of data pads. The second data path circuit is configured to transfer data between the third page buffer circuit or the fourth page buffer circuit and the second data pad set. The first data path circuit and the second data path circuit are electrically separated from each other.

According to an embodiment of the inventive concept, a non-volatile memory device includes a cell array including a first plane and a second plane, a first page buffer circuit configured to input data into the first plane, a second page buffer circuit configured to input data into the second plane, a first data pad set disposed on a first side surface of the cell array and connected to the first page buffer circuit through a first data path circuit, and a second data pad set disposed on a second side of the cell array at a different position from the first side surface and connected to the second page buffer circuit through a second data path circuit. The first data path circuit and the second data path circuit are electrically separated from each other.

### BRIEF DESCRIPTION OF THE FIGURES

The above and other objects and features of the present disclosure will become apparent by describing in detail embodiments thereof with reference to the accompanying drawings.

FIG. 1 is a block diagram showing a storage device according to an embodiment of the present invention.

FIG. 2 is a block diagram showing the structure of the non-volatile memory device of FIG. 1 in more detail.

FIG. 3 is a block diagram schematically showing the structure of a non-volatile memory device according to an embodiment of the present invention.

FIG. 4 is a circuit diagram showing an example structure of a memory block constituting the cell array of FIG. 2.

FIG. 5 is a plan view exemplarily showing the arrangement of data path circuits and data pad sets shown in FIG. 2.

FIG. 6 is a diagram showing a first data pad set and a first data path circuit of FIG. 5 in more detail.

FIG. 7 is a diagram showing a second data pad set and a second data path circuit of FIG. 5 in more detail.

FIG. 8 is a block diagram showing an embodiment of the non-volatile memory device of FIG. 1.

FIG. 9 is a plan view exemplarily showing the arrangement of the data path circuits and data pad sets shown in FIG. 8.

FIG. 10 is a plan view showing an expanded embodiment of the arrangement of the data path circuits and data pad sets shown in FIG. 9.

FIG. 11 is a plan view showing another example of the arrangement of the data path circuits and data pad sets shown in FIG. 2.

FIG. 12 is a diagram illustrating the configuration of the data pad set of FIG. 11.

FIG. 13 is a diagram showing another example of the configuration of the data pad set of FIG. 11.

### DETAILED DESCRIPTION

It is to be understood that both the foregoing general description and the following detailed description are exemplary, and thus the claimed invention is not limited thereto. Reference numbers are indicated in detail in embodiments of the present invention, examples of which are indicated in the reference drawings. Wherever possible, the same reference numbers are used in the description and drawings to refer to the same or like parts.

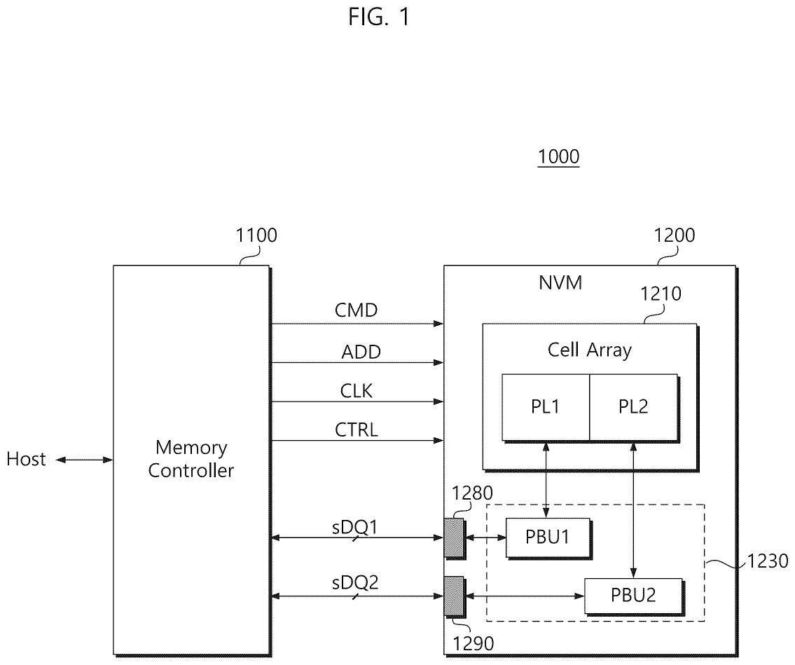

FIG. 1 is a block diagram showing a storage device according to an embodiment of the present invention. Referring to FIG. 1, the storage device 1000 includes a memory controller 1100 (e.g., a controller circuit) and a non-volatile memory device 1200. Data requested by a host to be written may be stored in the non-volatile memory device 1200 under the control of the memory controller 1100. By way of example, the storage controller 1100 and the non-volatile memory device 1200 may each be provided as one chip, one package, or one module. Alternatively, the storage controller 1100 and the nonvolatile memory device 1200 may be formed of one chip, one package, or one module. The storage controller 1100 and the non-volatile memory device 1200 may be provided as storage such as an embedded memory, a memory card, a memory stick, or a solid state drive SSD.

The memory controller 1100 writes data to the non-volatile memory device 1200 or reads data stored in the non-volatile memory device 1200 at the request of the host. The memory controller 1100 provides the non-volatile memory device 1200 with a command CMD, an address ADDR, a clock signal CLK, and a control signal CTRL for accessing the non-volatile memory device 1200. Also, during a write operation, the memory controller 1100 can supply data to different memory areas or receive data from these different memory areas through the first and second data lines sDQ1 and sDQ2 that are electrically separated.

The first data line sDQ1 is allocated to the first plane PL1 of the non-volatile memory device 1200, and the second data line sDQ2 is allocated to the second plane PL2 of the non-volatile memory device 1200. In other words, the first data line sDQ1 and the second data line sDQ2 of the memory controller 1100 are data lines allocated to different memory areas of the nonvolatile memory device 1200. The memory controller 1100 transmits a command CMD, an address ADDR, a clock signal CLK, and a control signal CTRL to the nonvolatile memory device 1200 in response to the host's access request (e.g., a request signal from the host). Additionally, the storage controller 1100 may select one of the first data line sDQ1 and the second data line sDQ2 according to a target area being accessed. For example, the target area could be the first plane PL1 or the second plane PL2. Here, it has been described as an example that the allocation areas of the first data line sDQ1 and the second data line sDQ2 are in plane units, but the present invention is not limited thereto. The allocation unit of the first data line sDQ1 and the second data line sDQ2 may be a block unit, or, if necessary, may be a memory unit of various sizes. For example, the target area could be one or more blocks of one of the planes.

The nonvolatile memory device 1200 may include a cell array 1210 and a page buffer circuit 1230. The cell array 1210 may include a plurality of planes (e.g., PL1, PL2, etc.) each of which includes a plurality of memory blocks. Each of the plurality of memory blocks may have a vertical three-dimensional structure. Each memory block may be composed of a plurality of memory cells. The cell array 1210 may be located adjacent a side of the page buffer circuit or above the page buffer circuit 1230 in terms of layout structure. In other words, the cell array 1210 may be formed in a cell-on-peripheral COP structure located above the page buffer circuit 1230. The cell array 1210 may be manufactured as a separate chip from the page buffer circuit 1230. An upper chip including the cell array 1210 and a lower chip including the page buffer circuit 1230 may be connected to each other using a bonding method.

The page buffer circuit 1230 may include analog circuits or digital circuits to store data in the cell array 1210 or read data stored in the cell array 1210. The page buffer circuit 1230 receives write data transmitted via the first data pad set 1280 or the second data pad set 1290. Write data is transferred from the memory controller 1100 to the first data pad set 1280 through data line sDQ1 or and to the second data pad set 1290 through data line sDQ2. The page buffer circuit 1230 may program the received write data into the selected memory area. The page buffer circuit 1230 senses data requested to be read from the memory controller 1100 from the selected memory area. The page buffer circuit 1230 transfers the sensed data to the first data line sDQ1 via the first data pad set 1280 or to the second data line sDQ2 via the second data pad set 1290.

The first data pad set 1280 transmits data input through the first data line sDQ1 to a first page buffer unit PBU1 (e.g., a first buffer circuit) and transfers data input through the second data line sDQ2 to a second page buffer unit PBU2 (e.g., a second buffer circuit). The first data pad set 1280 transmits data output from the first page buffer unit PBU1 to the first data line sDQ1 and transmits data output from the second page buffer unit PBU2 to the second data line sDQ2. Each of the first data pad set 1280 and the second data pad set 1290 may include a plurality of data pads. For example, the first data pad set 1280 and the second data pad set 1290 may each include 8 or 16 data pads.

When the first data pad set 1280 includes 8 data pads, the first data pad set 1280 can transfer 1-byte data to the page buffer unit PBU1 corresponding to the first plane PL1. In addition, a data path circuit such as a multiplexer MUX may be further included between the first data pad set 1280 and the first page buffer unit PBU1.

Meanwhile, the first data pad set 1280 and the second data pad set 1290 may be disposed on different sides of the nonvolatile memory device 1200. In an embodiment, the first data pad set 1280 is disposed on a first side of the die on which the non-volatile memory device 1200 is formed, and the second data pad set 1290 is disposed on the second side of the die. In an embodiment, the side on which the first data pad set 1280 and the second data pad set 1290 are disposed is selected to minimize the length of a data path for electrical connection with the page buffer units PBU1 and PBU2. These features will be explained in more detail through the drawings described later.

In the above, the configuration of the storage device 1000 of the present invention has been briefly described. In particular, the nonvolatile memory device 1200 of the present invention may be provided with a dedicated data pad set for each memory unit (e.g., plane). Additionally, the data pad sets may be disposed on different sides of the non-volatile memory device 1200 to minimize the data path length between page buffer units corresponding to each memory unit. Through this structure, the number of data pads of the nonvolatile memory device 1200 can be increased. Ultimately, a non-volatile memory device 1200 capable of high-bandwidth data input and output and capable of reducing power consumption by minimizing the length of the data path can be implemented.

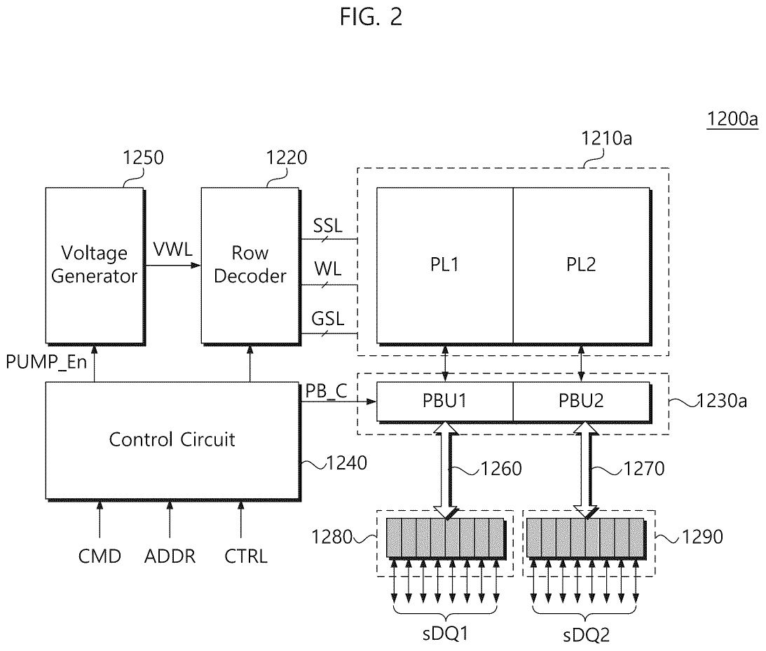

FIG. 2 is a block diagram showing the structure of the non-volatile memory device of FIG. 1 in more detail. Referring to FIG. 2, a nonvolatile memory device 1200a according to an embodiment includes a cell array 1210a, a row decoder 1220 (e.g., a decoder circuit), a page buffer circuit 1230a, a control circuit 1240, a voltage generator 1250, data path circuits 1260 and 1270, a first data pad set 1280, and a second data pad set 1290.

The cell array 1210a includes a plurality of planes PL1 and PL2, each of which includes a plurality of memory blocks. Each of the plurality of memory blocks may have a vertical three-dimensional structure. Each memory block may consist of a plurality of pages. Each page may be composed of a plurality of memory cells. Each memory block may be an erase unit, and each page may be a read or write unit. Here, the plurality of planes PL1 and PL2 are shown as two planes, but the present invention is not limited thereto. For example, the plurality of planes may include three or more planes.

The cell array 1210a may be formed in a direction perpendicular to a substrate. Gate electrode layers and insulation layers may be deposited alternately on the substrate. Each memory block may be connected to a string selection line SSL, a plurality of word lines WL, and a ground selection line GSL. The number of stacks of gate electrode films on which the word lines of the cell array 1210a are formed may increase as product generations advance.

The row decoder 1220 may select a word line of the cell array 1210a in response to the address ADDR. The row decoder 1220 provides the word line voltage VWL provided from the voltage generator 1250 to the cell array 1210a through the selection lines SSL and GSL and word lines WL. The row decoder 1220 can select a word line during a program or read operation. The row decoder 1220 may provide a program voltage or a read voltage to the selected word line.

The page buffer circuit 1230a may be connected to the cell array 1210a through one or more bit lines. The page buffer circuit 1230a may precharge or sense bit lines connected to memory cells in response to a page buffer control signal PB_C provided from the control circuit 1240. The page buffer circuit 1230a may include a plurality of page buffer units PBU1 and PBU2. Each of the page buffer units PBU1 and PBU2 may include a plurality of page buffers. A plurality of page buffers may each be connected to memory cells through a plurality of bit lines.

The page buffer circuit 1230a may operate as a write driver or a sense amplifier depending on the operation mode. For example, during the program operation, the page buffer circuit 1230a may apply a bit line voltage corresponding to data to be programmed to the selected bit line. During the read operation, the page buffer circuit 1230a may detect data stored in the memory cell by detecting the current or voltage of the selected bit line.

The control circuit 1240 can control various operations within the nonvolatile memory device 1200a according to an operation mode. The control circuit 1240 may perform program, read, erase operations in response to the control signal CTRL, a command CMD, and/or an address ADDR. For example, the control circuit 1240 may generate a pump enable signal PUMP_En, and a page buffer control signal PB_C for program operation. The control circuit 1240 provides the pump enable signal PUMP_En to the voltage generator 1250 to generate the voltage used for read, write, and erase operations.

The voltage generator 1250 may generate the word line voltage VWL used to read or write data in response to the pump enable signal PUMP_En from the control circuit 1240. The word line voltage VWL may be provided to a selected word line or an unselected word line through the row decoder 1220. The voltage generator 1250 may include a charge pump (not shown) for this purpose. A memory cell connected to the selected word line is currently being accessed during a memory access operation whereas a memory cell connected to the unselected word line is not currently being accessed during the memory access operation. The voltage generator 1250 may generate a word line voltage provided during the program operation or a word line voltage provided during the read operation.

The data path circuits 1260 and 1270 provide electrical connections for data transfer between the page buffer units PBU1 and PBU2 and the data pad sets 1280 and 1290. In other words, the first page buffer unit PBU1 connected to the first plane PL1 is connected to the first data pad set 1280 through the first data path circuit 1260. The first data path circuit 1260 may include a conductive line including a via and a metal line or wire. Alternatively, the first data path circuit 1260 may include driver circuits to enhance a signal level. In an embodiment, the first page buffer unit PBU1 is formed in a periphery region of a lower layer of a semiconductor layer, and the first data pad set 1280 is formed in an upper layer of the semiconductor layer where the cell array 1210a is formed. Accordingly, the distance between the first page buffer unit PBU1 and the first data pad set 1280 becomes relatively long, and signal strength may need to be strengthened through driver circuits.

In addition, the second page buffer unit PBU2 connected to the second plane PL2 is connected to the second data pad set 1290 through the second data path circuit 1270. Like the first data path circuit 1260, the second data path circuit 1270 may also include conductive lines including vias, metal lines, and wires, or driver circuits for amplifying the signal level.

The first data pad set 1280 is provided to connect the first page buffer unit PBU1 and an external device. In other words, the first data line sDQ1 connected to the memory controller 1100 (see FIG. 1) is connected to the first data pad set 1280. The first data pad set 1280 transmits data to be programmed in the first plane PL1 input through the first data line sDQ1 to the first page buffer unit PBU1 via the first data path circuit 1260. Read data of the first plane PL1 sensed by the first page buffer unit PBU1 is transmitted to the first data line sDQ1 via the first data path circuit 1260 and the first data pad set 1280.

The second data pad set 1290 is provided to connect the second page buffer unit PBU2 and the memory controller 1100. In other words, the second data line sDQ2 connected to the memory controller 1100 is connected to the second data pad set 1290. The second data pad set 1290 transmits data to be programmed in the second plane PL2 input through the second data line sDQ2 to the second page buffer unit PBU2 via the second data path circuit 1270. Read data of the second plane PL2 sensed by the second page buffer unit PBU2 is transmitted to the second data line sDQ2 via the second data path circuit 1270 and the second data pad set 1290. The first data pad set 1280 and the second data pad set 1290 may include a data pad DQ_P and a date strobe signal pad DQS_P, respectively.

In an embodiment, the first data pad set 1280 and the second data pad set 1290 are on different sides of a die on which the non-volatile memory device 1200 is formed. Accordingly, a geometric structure that can minimize the path lengths of the first data path circuit 1260 and the second data path circuit 1270 can be implemented. In other words, the first data pad set 1280 may be disposed on the first side where the distance between the first page buffer unit PBU1 and the first data pad set 1280 is minimized. Likewise, the second data pad set 1290 may be disposed on the second side where the distance between the second page buffer unit PBU2 and the second data pad set 1290 is minimized. Accordingly, the number of data path elements, metal lines, or drivers according to the lengths of the first data path circuit 1260 and the second data path circuit 1270 can be minimized.

A set of command, address, and clock signal pads may be formed on the second side where the second data pad set 1290 is disposed. In an embodiment, the first side where the first data pad set 1280 is disposed includes a power pad for signal driving, a pad set (e.g., reference voltage pad) for setting the level of an input/output signal, and a data strobe signal DQS pad set may be further included. In addition, the first data pad set 1280 and the second data pad set 1290 may be completely electrically separated and driven independently.

In an embodiment, according to the non-volatile memory device 1200a of the present invention, the first data pad set 1280 and the second data pad set 1290, which are responsible for input and output of different memory areas, are disposed on different sides of the die. Accordingly, the first data path circuit 1260 and the second data path circuit 1270 may be connected to the shorter path among the first page buffer unit PBU1 and the second page buffer unit PBU2. Through this, it is possible to implement a low-power and low-cost nonvolatile memory device 1200a to support a high-bandwidth input/output interface. The technology of the present invention can be applied to next-generation wide I/O flash memory devices because the data pad set according the above-described embodiment can be expanded.

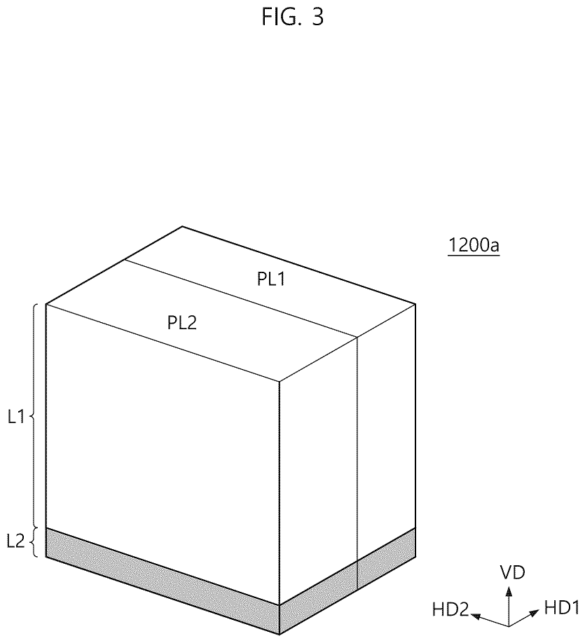

FIG. 3 is a block diagram schematically showing the structure of a non-volatile memory device according to an embodiment of the present invention. Referring to FIG. 3, the nonvolatile memory device 1200a includes a first semiconductor layer L1 and a second semiconductor layer L2, where the first semiconductor layer L1 can be stacked in the vertical direction VD with respect to the second semiconductor layer L2. Specifically, the second semiconductor layer L2 may be disposed below the first semiconductor layer L1 in the vertical direction VD, and accordingly, the second semiconductor layer L2 may be disposed close to the substrate. For example, the second semiconductor layer L2 or some elements of the second semiconductor layer L2 may be disposed closer to the substrate than the first semiconductor layer L1.

In an embodiment, the cell array 1210a of FIG. 2 is disposed in the first semiconductor layer L1, and the row decoder 1220 of FIG. 2, the page buffer circuit 1230a, the control circuit 1240, and peripheral circuits corresponding to the voltage generator 1250 are disposed in the second semiconductor layer L2. Accordingly, the nonvolatile memory device 1200a may have a structure in which the cell array 1210a is disposed on top of the peripheral circuits 1220, 1230, 1240, and 1250, In other words, a cell over periphery COP structure. The COP structure can effectively reduce the horizontal area and increase the integration of the nonvolatile memory device 1200a.

In an embodiment, the second semiconductor layer L2 includes a substrate, and the peripheral circuits 1220, 1230a, 1240 and 1250 are formed on the second semiconductor layer L2 by forming transistors and metal patterns for wiring the transistors on the substrate. After the peripheral circuits 1220, 1230a, 1240, and 1250 are formed in the second semiconductor layer L2, the first semiconductor layer L1 including the cell array 1210a may be formed, and the metal patterns may be formed to electrically connect the word lines WL and bit lines BL and the peripheral circuits 1220, 1230a, 1240, and 1250 formed in the second semiconductor layer L2. For example, the bit lines BL may extend in a first horizontal direction HD1, and the word lines WL may extend in the second horizontal direction HD2. For example, the first horizontal direction HD1 may cross or intersect the second horizontal direction HD2.

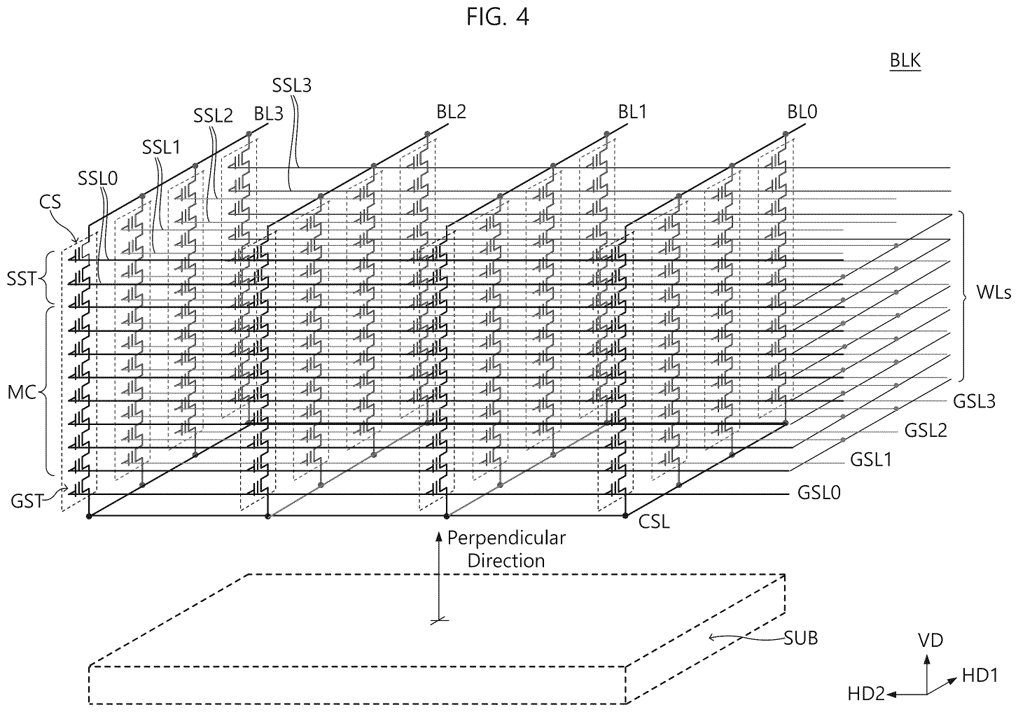

FIG. 4 is a circuit diagram showing an example structure of a memory block constituting the cell array of FIG. 2. Referring to FIG. 4, cell strings CS are located between the bit lines BL0, BL1, BL2, and BL3 and the common source line CSL to form the memory block BLK.

A plurality of cell strings are located between the bit line BL0 and the common source line CSL. The string selection transistor SST of the cell strings CS is connected to the corresponding bit line BL. The ground selection transistor GST of the cell strings CS is connected to the common source line CSL. Memory cells MCs are provided between the string selection transistor SST and the ground selection transistor GST of the cell string CS.

Each of the cell strings CS includes the ground selection transistor GST. Ground selection transistors included in the cell strings CS may be controlled by the ground selection lines GSL (e.g., GSL0, GSL1, GSL2, GSL3, etc.). Alternatively, cell strings corresponding to each row may be controlled by different ground selection lines.

Above, the circuit structure of memory cells included in one memory block BLK was briefly described. However, the circuit structure of the illustrated memory block is only a simplified structure for convenience of explanation, and the actual memory block is not limited to the illustrated example. In other words, one physical block may include more semiconductor layers, bit lines BLs, and string select lines SSLs (e.g., SSL0, SSL1, SSL2, SSL3, etc.).

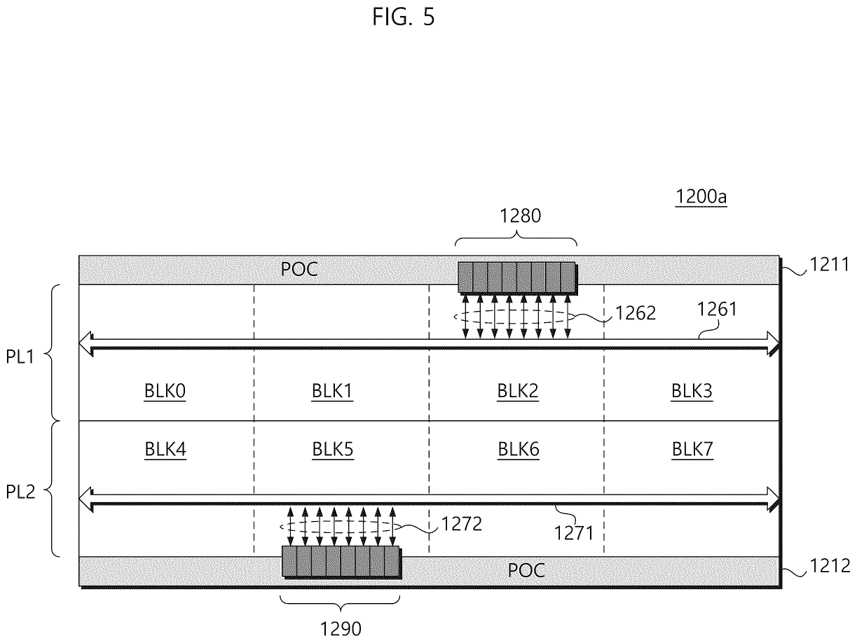

FIG. 5 is a plan view exemplarily showing the arrangement of the data path circuits and data pad sets shown in FIG. 2 according to an embodiment. Referring to FIG. 5, data pad sets 1280 and 1290 corresponding to each of the planes PL1 and PL2 are disposed on different side surfaces 1211 and 1212 of the nonvolatile memory device 1200a. In an embodiment, the side surface is an area where pads can be formed on four side surfaces of a rectangular die on which a nonvolatile memory device 1200a is formed. The side surfaces 1211 and 1212 may oppose one another.

The first plane PL1 may include four memory blocks BLK0, BLK1, BLK2, and BLK3 in the cell array 1210a area. A first data path circuit 1260 connecting a first page buffer unit (PBU1) composed of page buffers for each of memory blocks BLK0, BLK1, BLK2 and BLK3 and a first data pad set 1280 may be provided. Here, the first data path circuit 1260 includes a first data bus 1261 and a second data bus 1262. The first data bus 1261 may be a data line circuit shared by page buffers of each of the memory blocks BLK0, BLK1, BLK2, and BLK3. The second data bus 1262 may be a data line circuit that provides an electrical connection between the first data bus 1261 and the first data pad set 1280.

The second plane PL2 may include four memory blocks BLK4, BLK5, BLK6, and BLK7 in the cell array 1210a area. A second data path circuit 1270 connecting a second page buffer unit (PBU2) composed of page buffers for each of memory blocks BLK4, BLK5, BLK6 and BLK7 and a second data pad set 1290 may be provided. Here, the second data path circuit 1270 may include a third data bus 1271 and a fourth data bus 1272. The third data bus 1271 may be a data line circuit shared by page buffers of each of the memory blocks BLK4, BLK5, BLK6, and BLK7, and the fourth data bus 1272 may be a data line circuit that provides an electrical connection between the third data bus 1271 and the second data pad set 1290.

In particular, the first data pad set 1280 and the second data pad set 1290, which are dedicated to input and output of different memory areas (e.g., PL1 and PL2), may be located on different die sides of the nonvolatile memory device 1200a. Accordingly, the overall length of the first data path circuit 1260 and the second data path circuit 1270 is reduced compared to when the first data pad set 1280 and the second data pad set 1290 are located on one side. In other words, the length of the second data bus 1262 or the fourth data bus 1272 can be reduced by forming the first data pad set 1280 on the first side surface 1211 of the nonvolatile memory device 1200a, and the second data pad set 1290 on the second side surface 1212 of the nonvolatile memory device 1200a. In other words, compared to the case where the first data pad set 1280 and the second data pad set 1290 are located on one side, the length of the second data bus 1262 or the fourth data bus 1272 can be reduced.

Here, the first data pad set 1280 and the second data pad set 1290 may be formed in a pad-on-cells (hereinafter referred to as POC) structure that is formed by overlapping the upper portion of the cell array 1210 as well as the area where the pads are formed.

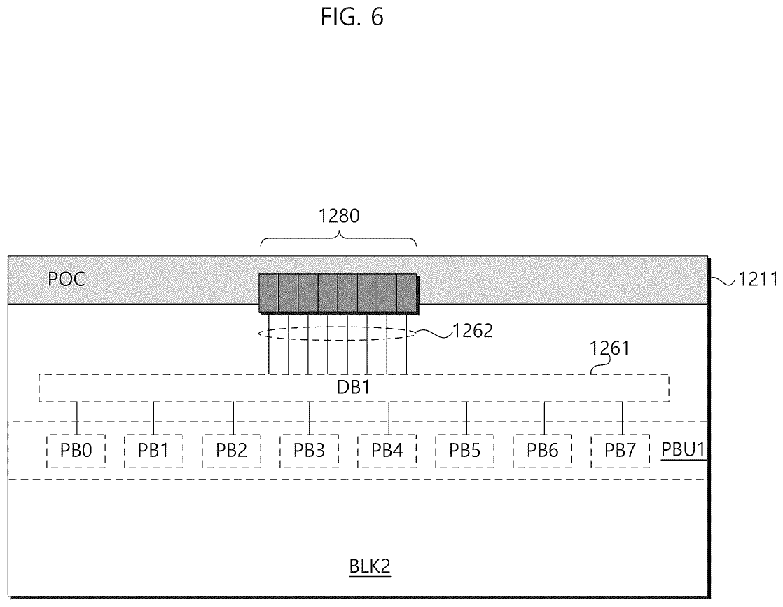

FIG. 6 is a diagram showing the first data pad set and the first data path circuit of FIG. 5 in more detail. Referring to FIG. 6, the first data pad set 1280 may be located in a partial area (e.g., BLK2) of the cell array 1210 and the first side surface 1211 for forming the pad. In other words, the first data pad set 1280 may be formed over the cell array 1210 and the first side surface 1211 in a pad-on-cell POC structure.

The first page buffer unit PBU1 and a portion of the first data path circuit 1260 for inputting and outputting data to the memory area of the first plane PL1 may be formed in the lower layer of the cell array 1210a. In other words, the first page buffer unit PBU1 composed of a plurality of page buffers PB0 to PB7 may be formed in a peripheral circuit area located in the lower layer of the cell array 1210a. Additionally, the first data bus 1261 disposed between the plurality of page buffers PB0 to PB7 and the first data pad set 1280 may also be disposed in the peripheral circuit area disposed in the lower layer of the cell array 1210a. In an embodiment, the second data bus 1262 connecting the first data bus 1261 and the first data pad set 1280 has conductive lines including a via penetrating into the upper part of the cell array 1210a area.

Although the location where the first data pad set 1280 is formed is shown as being located on the side of the memory block BLK2 of the cell array 1210a, the present invention is not limited thereto. In other words, the first data pad set 1280 formed for data input/output to the first plane PL1 may be formed on any one side of the memory blocks BLK0, BLK1, BLK2 and BLK3 constituting the first plane PL1. Alternatively, the first data pad set 1280 may be formed scattered on the sides of the memory blocks BLK0, BLK1, BLK2, and BLK3 constituting the first plane PL1.

The first data bus 1261 and the second data bus 1262 may be composed of a combination of conductive lines, but may also be composed of a circuit such as a driver or multiplexer MUX to reinforce the signal level of data. Alternatively, the first data bus 1261 and the second data bus 1262 may include a reference circuit for controlling the level of the signal.

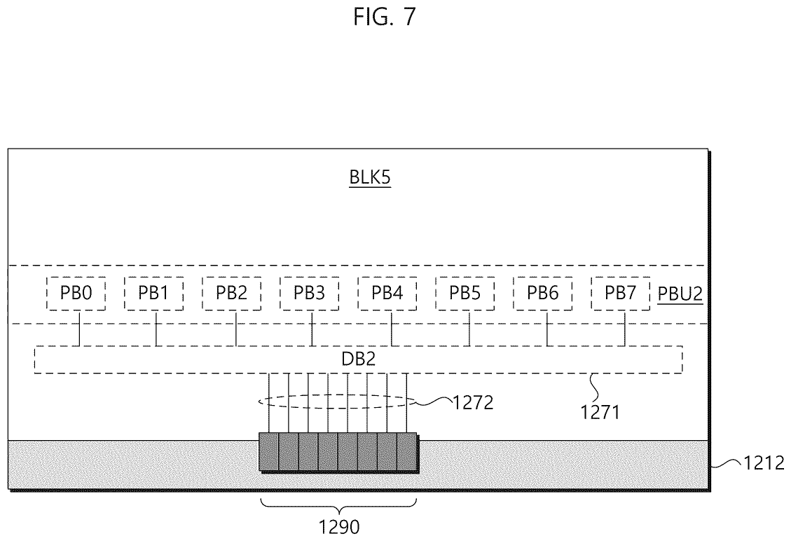

FIG. 7 is a diagram showing the second data pad set and the second data path circuit of FIG. 5 in more detail. Referring to FIG. 7, the second data pad set 1290 may be located in a partial area (e.g., BLK5) of the cell array 1210a and the second side surface 1212 to form a pad. In other words, the second data pad set 1290 may be formed over the cell array 1210a and the second side surface 1212 in a pad-on-cell POC structure.

The second page buffer unit PBU2 and a portion of the second data path circuit 1270 for inputting and outputting data to the memory area of the second plane PL2 may be formed in a lower layer of the cell array 1210a. In other words, the second page buffer unit PBU2 composed of a plurality of page buffers PB0 to PB7 may be disposed in a peripheral circuit area disposed at the bottom of the cell array 1210a. Additionally, the third data bus 1271 disposed between the plurality of page buffers PB0 to PB7 and the second data pad set 1290 may also be disposed in the peripheral circuit area disposed in the lower layer of the cell array 1210a. In an embodiment, the fourth data bus 1272 connecting the third data bus 1271 and the second data pad set 1290 includes a via or various conductive lines penetrating into the upper part of the cell array 1210a area.

Although the second data pad set 1290 is shown as being located on the side of the memory block BLK5 of the cell array 1210a, the present invention is not limited thereto. In other words, the second data pad set 1290 formed for data input/output to the second plane PL2 can be formed on the side of any one of the memory blocks BLK4, BLK5, BLK6, and BLK7 constituting the second plane PL2. Alternatively, the second data pad set 1290 may be formed scattered on the sides of the memory blocks BLK4, BLK5, BLK6, and BLK7 constituting the second plane PL2.

The third data bus 1271 and the fourth data bus 1272 may be composed of a combination of conductive lines, but may also be composed of a circuit such as a driver or multiplexer MUX to reinforce the signal level of data. Alternatively, the third data bus 1271 and the fourth data bus 1272 may include a reference circuit for controlling the magnitude of the signal level.

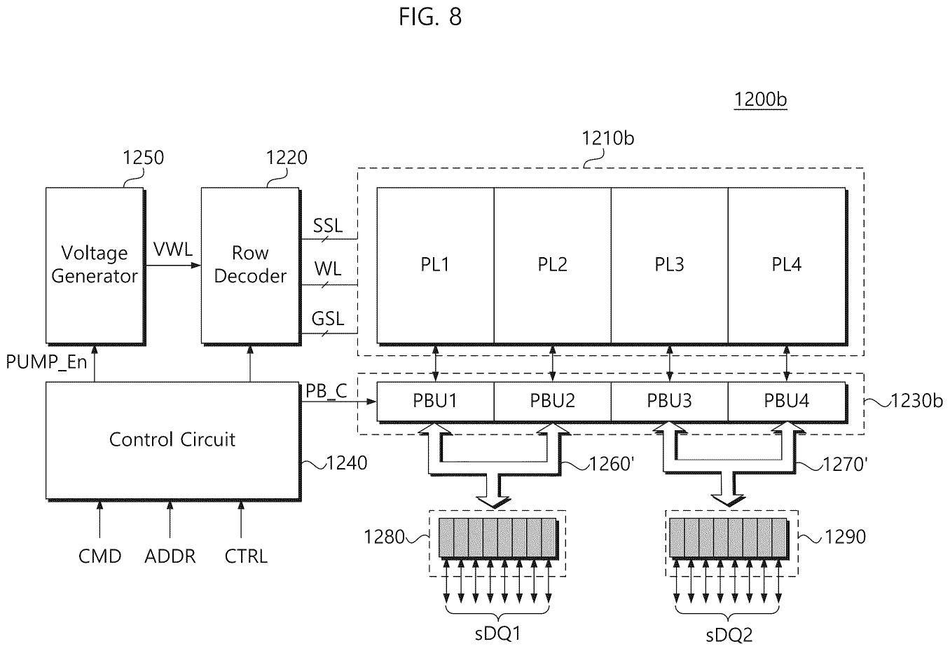

FIG. 8 is a block diagram showing an embodiment of the nonvolatile memory device of FIG. 1. Referring to FIG. 8, the non-volatile memory device 1200b includes a cell array 1210b, a row decoder 1220 (e.g., a decoder circuit), a page buffer circuit 1230b, a control circuit 1240, a voltage generator 1250, and data path circuits 1260′ and 1270′, a first data pad set 1280 and a second data pad set 1290. Here, the configuration and functions of the row decoder 1220, control circuit 1240, and voltage generator 1250 are substantially the same as those in FIG. 2. Therefore, description of these will be skipped.

The cell array 1210b includes a plurality of planes PL1, PL2, PL3, and PL4, each of which includes a plurality of memory blocks. Here, the plurality of planes PL1, PL2, PL3, and PL4 are shown as four planes, but the present invention is not limited thereto. For example, the plurality of planes PL1, PL2, PL3, and PL4 may include five or more planes. The cell array 1210b may be formed in a direction perpendicular to the substrate. Gate electrode layers and insulation layers may be deposited alternately on the substrate. Each memory block may be connected to a string selection line SSL, a plurality of word lines, and a ground selection line GSL.

The page buffer circuit 1230b may be connected to the cell array 1210b through bit lines. The page buffer circuit 1230b may precharge or sense bit lines connected to memory cells in response to the page buffer control signal PB_C provided from the control circuit 1240. The page buffer circuit 1230b may include a plurality of page buffer units PBU1, PBU2, PBU3, and PBU4. Each of the page buffer units PBU1, PBU2, PBU3, and PBU4 (e.g., buffer circuits) may include a plurality of page buffers. The plurality of page buffers may each be connected to memory cells through the bit lines.

Data path circuits 1260′ and 1270′ provide electrical connections for data transfer between page buffer units PBU1, PBU2, PBU3, and PBU4 and data pad sets 1280 and 1290. In other words, the page buffer units PBU1 and PBU2 connected to the first plane PL1 and the second plane PL2 are connected to the first data pad set 1280 through the first data path circuit 1260′. The first data path circuit 1260′ may include various conductive lines including vias and metal lines or wires, or driver circuits for amplifying signal levels. Additionally, the first data path circuit 1260′ may include a selection circuit or multiplexer for connecting one of the page buffer units PBU1 and PBU2 to the first data pad set 1280.

In addition, the page buffer units PBU3 and PBU4 connected to the third plane PL3 and the fourth plane PL4 are connected to the second data pad set 1290 through the second data path circuit 1270′. The second data path circuit 1270′ may include various conductive lines including vias and metal lines or wires, or driver circuits for amplifying the signal level. Additionally, the second data path circuit 1270′ may also include a selection circuit or multiplexer for connecting one of the page buffer units PBU3 and PBU4 to the second data pad set 1290.

The first data pad set 1280 is provided to connect the page buffer units PBU1 and PBU2 to an external device. In other words, the first data line sDQ1 connected to the memory controller 1100 (see FIG. 1) is connected to the first data pad set 1280. The first data pad set 1280 transfers data to be programmed to the planes PL1 and PL2 input through the first data line sDQ1 to the page buffer units PBU1 and PBU2 via the first data path circuit 1260′. Data of the planes PL1 and PL2 sensed by the page buffer units PBU1 and PBU2 may be transmitted through the first data path circuit 1260′ and the first data pad set 1280 to the first data line sDQ1.

The second data pad set 1290 is provided for electrical connection between the page buffer units PBU3 and PBU4 and the memory controller 1100. In other words, the second data line sDQ2 connected to the memory controller 1100 is electrically connected to the second data pad set 1290. The second data pad set 1290 transmits data to be programmed in the planes PL3 and PL4 input through the second data line sDQ2 to the page buffer units PBU3 and PBU4 via the second data path circuit 1270′. The data of the planes PL3 and PL4 sensed by the page buffer units PBU3 and PBU4 may be transmitted to the second data line sDQ2.

In an embodiment, the first data pad set 1280 and the second data pad set 1290 are formed on different side surfaces of the die on which the nonvolatile memory device 1200b is formed. Accordingly, a geometric structure that can minimize the path lengths of the first data path circuit 1260′ and the second data path circuit 1270′ can be provided. In other words, the first data pad set 1280 may be placed on the side surface of the die where the distance between the page buffer units PBU1 and PBU2 and the first data pad set 1280 is minimized. Likewise, the second data pad set 1290 may be placed on the side surface of the die where the distance between the page buffer units PBU3 and PBU4 and the second data pad set 1290 is minimized. Accordingly, the number of path elements, metal lines, or drivers according to the length of the first data path circuit 1260′ and the second data path circuit 1270′ may be minimized.

In an embodiment, the first data pad set 1280 further includes a power pad for driving a signal, and a pad set for setting the level of an input/output signal (e.g., a reference level pad). In an embodiment, the command, address, and clock signal pad sets are allocated only to the side surface where the second data pad set 1290 is placed. In an embodiment, the first data pad set 1280 and the second data pad set 1290 are completely electrically separated and driven independently.

In the above, according to the non-volatile memory device 1200b of the present invention, the first data pad set 1280 and the second data pad set 1290, which are responsible for input and output of different memory areas, can be formed on different side surfaces of the die. Accordingly, the first data path circuit 1260′ and the second data path circuit 1270′ may be connected to the shortest path among the page buffer units PBU1 and PBU2 and the page buffer units PBU3 and PBU4. Accordingly, a low-power and low-cost nonvolatile memory device 1200b to support a high-bandwidth input/output interface can be implemented.

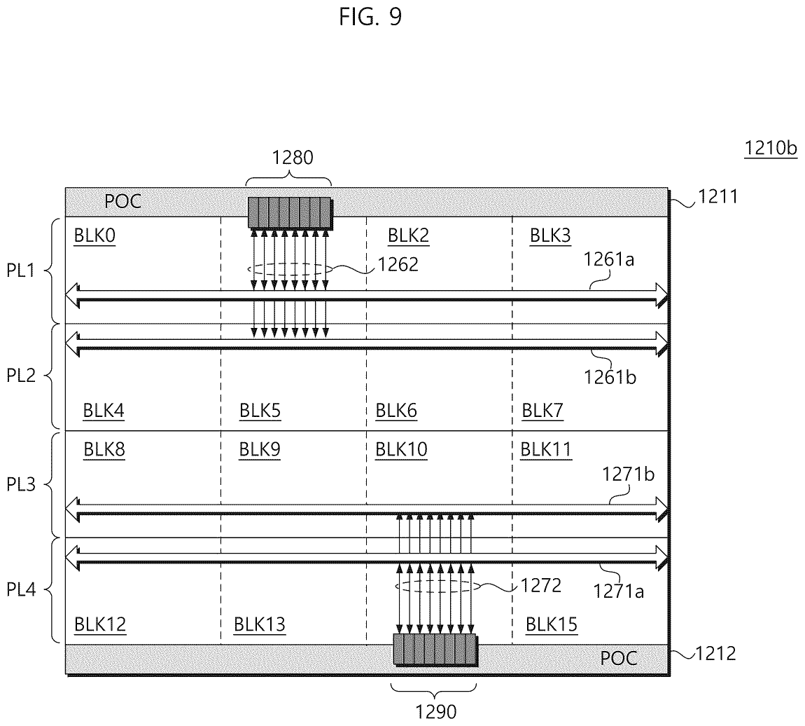

FIG. 9 is a plan view exemplarily showing the arrangement of the data path circuits and data pad sets shown in FIG. 8. Referring to FIG. 9, data pad sets 1280 and 1290 corresponding to each of the planes PL1, PL2, PL3, and PL4 may be disposed on different side surfaces of the nonvolatile memory device 1200.

The first and second planes PL1 and PL2 may together include eight memory blocks BLK0, BLK1, BLK2, BLK3, BLK4, BLK5, BLK6, and BLK7 in the cell array 1210b area. For example, the first plane PL1 may include BLK0-BLK3 and the second plane PL2 may include BL4-BLK7. A first data path circuit 1260′ may be provided that connects between the first and second page buffer units PBU1 and PBU2 consisting of page buffers for each of the memory blocks BLK0, BLK1, BLK2, BLK3, BLK4, BLK5, BLK6, and BLK7 and the first data pad set 1280. Here, the first data path circuit 1260′ includes first data buses 1261a and 1261b and a second data bus 1262. The first data bus 1261a may be a data line circuit shared by page buffers of each of the memory blocks BLK0, BLK1, BLK2, and BLK3 of the first plane PL1. Additionally, the first data bus 1261b may be a data line circuit shared by page buffers of each of the memory blocks BLK4, BLK5, BLK6, and BLK7 of the second plane PL2. The second data bus 1262 may be a data line circuit that electrically connects one of the first data buses 1261a and 1261b to the first data pad set 1280. Accordingly, a selection circuit or multiplexer for selecting a data path may be located between the first data buses 1261a and 1261b and the second data bus 1262. The second data bus 1262 may be disposed adjacent BLK1, but is not limited thereto.

The third and fourth planes PL3 and PL4 may together include eight memory blocks BLK8, BLK9, BLK10, BLK11, BLK12, BLK13, BLK14, and BLK15 in the cell array 1210b area. For example, the third plane PL3 may include BLK8-BLK11 and the fourth plane PL4 may include BL12-BLK15. A second data path circuit 1270′ may be provided that connects the third and fourth page buffer units PBU3 and PBU4 consisting of page buffers for each of the memory blocks BLK8, BLK9, BLK10, BLK11, BLK12, BLK13, BLK14, and BLK15 and a second data pad set 1290. Here, the second data path circuit 1270′ includes third data buses 1271a and 1271b and a fourth data bus 1272. The third data bus 1271a may be a data line circuit shared by page buffers of each of the memory blocks BLK12, BLK13, BLK14, and BLK15 of the fourth plane PL4. Additionally, the third data bus 1271b may be a data line circuit shared by page buffers of each of the memory blocks BLK8, BLK9, BLK10, and BLK11 of the third plane PL3. Additionally, the fourth data bus 1272 may be a data line circuit that electrically connects one of the third data buses 1271a and 1271b to the second data pad set 1290. A selection circuit or multiplexer for selecting a data path may be located between the third data buses 1271a and 1271b and the fourth data bus 1272. The fourth data bus 1272 may be disposed adjacent BLK4, but is not limited thereto.

In an embodiment, the first data pad set 1280 and the second data pad set 1290, which are dedicated to input/output of different memory areas, are formed on different die sides of the nonvolatile memory device 1200b. Accordingly, the overall length of the first data path circuit 1260′ and the second data path circuit 1270′ is shorter than when the first data pad set 1280 and the second data pad set 1290 are formed on one side. A first data pad set 1280 is formed on the first side surface 1211 of the non-volatile memory device 1200b, and a second data pad set 1290 is formed on the second side surface 1212 of the non-volatile memory device 1200b, thereby forming the second data bus 1262 or the fourth data bus 1272 to have minimal lengths. Ultimately, compared to the case where the first data pad set 1280 and the second data pad set 1290 are formed on one side, the length of the second data bus 1262 or the fourth data bus 1272 can be reduced.

Here, the first data pad set 1280 and the second data pad set 1290 may be formed in a pad-on-cell (hereinafter referred to as POC) structure that is formed by overlapping not only the area where the pad is formed but also the upper part of the cell array 1210.

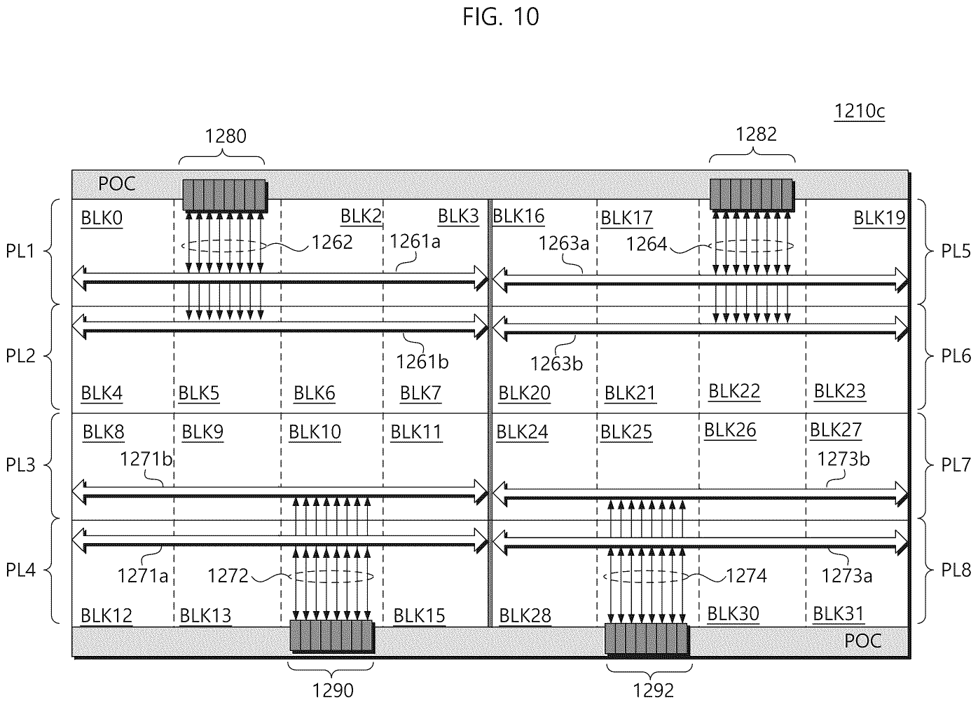

FIG. 10 is a plan view showing an expanded embodiment of the arrangement of the data path circuits and data pad sets shown in FIG. 9. Referring to FIG. 10, data pad sets 1280, 1282, 1290, and 1292 corresponding to each of the planes PL1, PL2, PL3, PL4, PL5, PL6, PL7, and PL8 may be arranged on different side of the non-volatile memory device 1200.

The first and second planes PL1 and PL2 may together include eight memory blocks BLK0, BLK1, BLK2, BLK3, BLK4, BLK5, BLK6, and BLK7 in the cell array 1210c area. In addition, a first data path circuit 1260′ may be provided connecting the page buffers of each of the memory blocks BLK0, BLK1, BLK2, BLK3, BLK4, BLK5, BLK6, and BLK7 and the first data pad set 1280. Here, the first data path circuit 1260′ includes first data buses 1261a and 1261b and a second data bus 1262. The first data bus 1261a may be a data line circuit shared by page buffers connected to the first plane PL1. Additionally, the first data bus 1261b may be a data line circuit shared by page buffers connected to the second plane PL2. The second data bus 1262 may be a data line circuit that electrically connects one of the first data buses 1261a and 1261b to the first data pad set 1280. A selection circuit or multiplexer for selecting a data path may be present between the first data buses 1261a and 1261b and the second data bus 1262.

The third and fourth planes PL3 and PL4 may together include eight memory blocks BLK8, BLK9, BLK10, BLK11, BLK12, BLK13, BLK14, and BLK15 in the cell array 1210c area. For example, the third plane PL3 may include BLK8-BLK11 and the fourth plane PL4 may include BLK12-BLK15. In addition, a second data path circuit 1270′ is provided that connects the page buffers of each of the memory blocks BLK8, BLK9, BLK10, BLK11, BLK12, BLK13, BLK14, and BLK15 and the second data pad set 1290. Here, the second data path circuit 1270′ includes third data buses 1271a and 1271b and a fourth data bus 1272. The third data bus 1271a may be a data line circuit shared by page buffers of each of the memory blocks BLK12, BLK13, BLK14, and BLK15 of the fourth plane PL4. Additionally, the third data bus 1271b may be a data line circuit shared by page buffers of each of the memory blocks BLK8, BLK9, BLK10, and BLK11 of the third plane PL3. Additionally, the fourth data bus 1272 may be a data line circuit that electrically connects one of the third data buses 1271a and 1271b to the second data pad set 1290. Accordingly, a selection circuit or multiplexer for selecting a data path may be present between the third data buses 1271a and 1271b and the fourth data bus 1272.

The fifth and sixth planes PL5 and PL6 may together include eight memory blocks BLK16, BLK17, BLK18, BLK19, BLK20, BLK21, BLK22, and BLK23. For example, the fifth plane PL5 may include BLK16-BLK19 and the sixth plane PL6 may include BLK20-BLK23. In addition, a third data path circuit 1260″ is provided that connects the page buffers of each of the memory blocks BLK16, BLK17, BLK18, BLK19, BLK20, BLK21, BLK22 and BLK23 and the third data pad set 1282. Here, the third data path circuit 1260″ includes fifth data buses 1263a and 1263b and a sixth data bus 1264. The fifth data bus 1263a may be a data line circuit shared by page buffers connected to the fifth plane PL5. Additionally, the fifth data bus 1263b may be a data line circuit shared by page buffers connected to the sixth plane PL6. The sixth data bus 1264 may be a data line circuit that electrically connects one of the fifth data buses 1263a and 1263b to the third data pad set 1282. A selection circuit or multiplexer for selecting a data path may be present between the fifth data buses 1263a and 1263b and the sixth data bus 1264. The sixth data bus 1264 may be disposed adjacent BLK18, but is not limited thereto.

The seventh and eighth planes PL7 and PL8 may together include eight memory blocks BLK24, BLK25, BLK26, BLK27, BLK28, BLK29, BLK30 and BLK31. For example, the seventh plane PL7 may include BLK24-BLK27 and the eighth plane PL8 may include BLK28-BLK31. In addition, a fourth data path circuit 1270″ is provided that connects the page buffers of each of the memory blocks BLK24, BLK25, BLK26, BLK27, BLK28, BLK29, BLK30 and BLK31 and the fourth data pad set 1292. Here, the fourth data path circuit 1270″ includes the seventh data buses 1273a and 1273b and the eighth data bus 1274. The seventh data bus 1273a may be a data line circuit shared by page buffers of each of the memory blocks BLK28, BLK29, BLK30, and BLK31 of the eighth plane PL8. Additionally, the seventh data bus 1273b may be a data line circuit shared by page buffers of each of the memory blocks BLK24, BLK25, BLK26, and BLK27 of the seventh plane PL7. Additionally, the eighth data bus 1274 may be a data line circuit that electrically connects one of the seventh data buses 1273a and 1273b to the fourth data pad set 1292. Accordingly, a selection circuit or multiplexer for selecting a data path may be present between the seventh data buses 1273a and 1273b and the eighth data bus 1274. The eighth data bus 1274 may be disposed adjacent BLK29, but is not limited thereto.

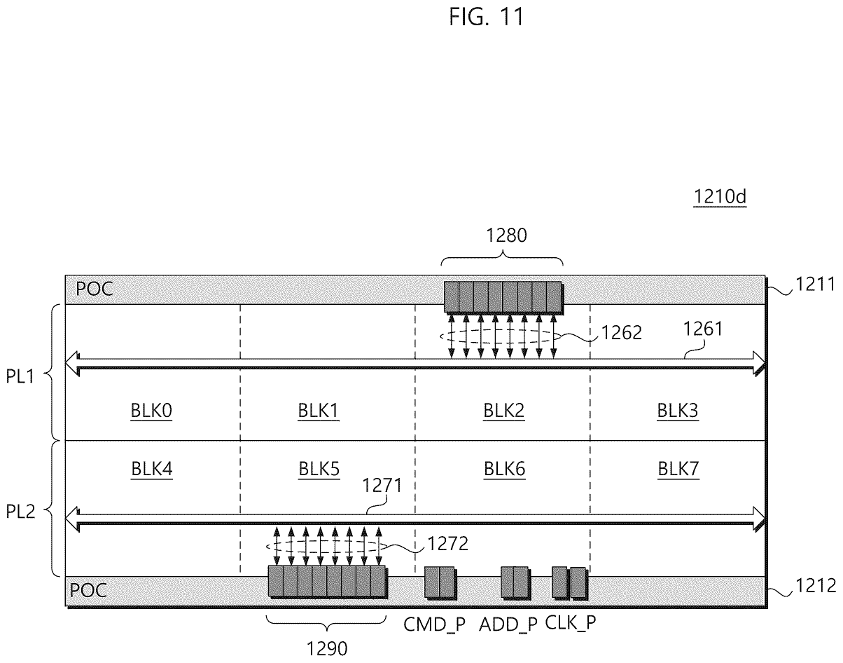

FIG. 11 is a plan view showing another example of the arrangement of the data path circuits and data pad sets shown in FIG. 2. Referring to FIG. 11, data pad sets 1280 and 1290 corresponding to each of the planes PL1 and PL2 may be disposed on different sides of the nonvolatile memory device 1200. The first and second planes PL1 and PL2 may together include eight memory blocks BLK0, BLK1, BLK2, BLK3, BLK4, BLK5, BLK6, and BLK7 in the cell array 1210d area.

A command pad CMD_P, an address pad ADD_P, and a clock signal pad CLK_P may be formed on the second side surface 1212 where the second data pad set 1290 is formed. Here, the command pad CMD_P may include at least one of pads to which a chip enable signal /CE, a command latch enable signal CLE, and an address latch enable signal ALE are input. The clock signal pad CLK_P may include at least one of pads for inputting a write enable signal /WE, a read enable signal /RE, and an external clock signal CLK.

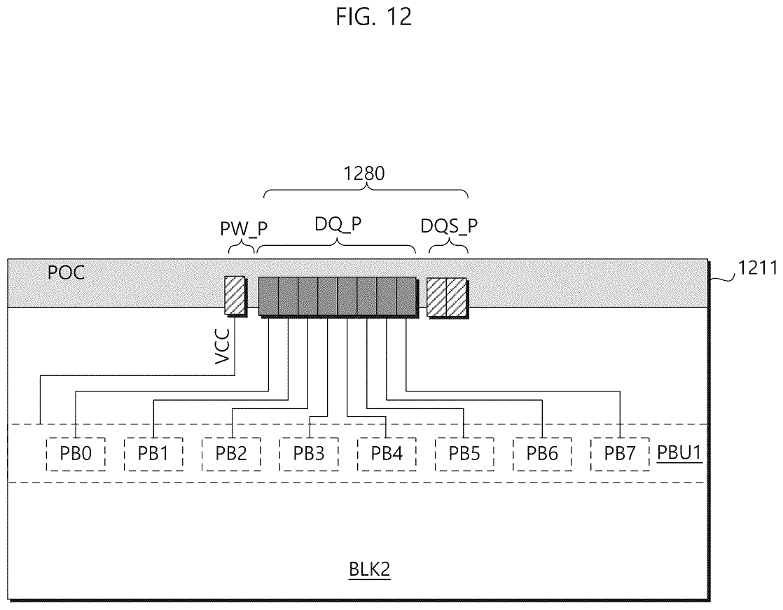

FIG. 12 is a diagram illustrating the configuration of the data pad set of FIG. 11. Referring to FIG. 12, a power pad PW_P may be disposed on the first side surface 1211 where the first data pad set 1280 is formed. In addition, the first data pad set 1280 may include a data signal pad DQ_P and a data strobe signal pad DQS_P.

A power supply voltage VCC provided to drive the data signal DQ may be provided to the power pad PW_P. The data signal pad DQ_P may be a pad for inputting or outputting the data signal DQ exchanged with the memory controller 1100 (see FIG. 1). The data strobe signal pad DQS_P may be a pad for transmitting the data strobe signal DQ.

The illustrated embodiment is described using the first data pad set 1280 as an example, but in another embodiment, the second data pad set 1290 may also include the same pads as the first data pad set 1280.

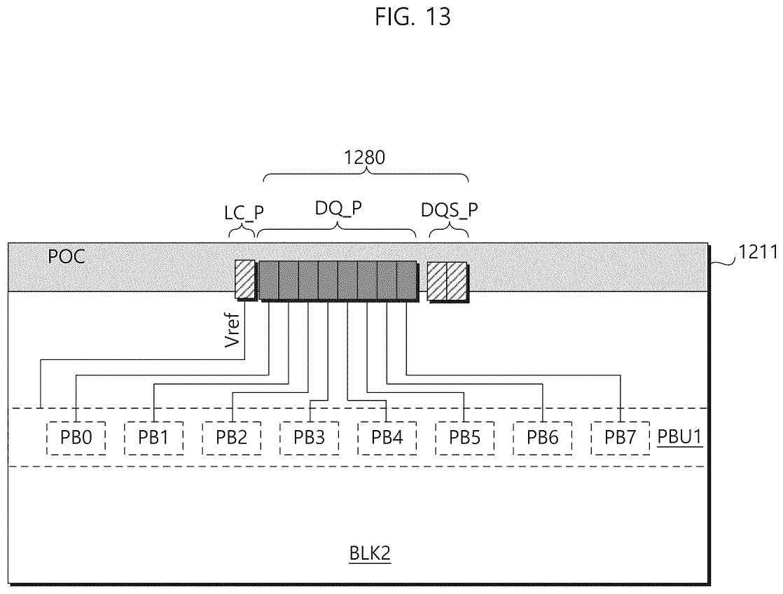

FIG. 13 is a diagram showing another example of the configuration of the data pad set of FIG. 11. Referring to FIG. 13, a level control pad LC_P may be formed on the first side surface 1211 where the first data pad set 1280 is formed. The first data pad set 1280 may include a data signal pad DQ_P and a data strobe signal pad DQS_P. A reference voltage Vref for controlling the level of the data signal DQ may be provided to the level control pad LC_P.

The illustrated embodiment is described using the first data pad set 1280 as an example, but in another embodiment, the second data pad set 1290 may also include the same pads as the first data pad set 1280.

The above are specific embodiments for carrying out the present invention. In addition to the above-described embodiments, the present invention may include simple design changes or easily changeable embodiments. In addition, the present invention may include techniques that can be easily modified and implemented using the embodiments. Therefore, the scope of the present invention is not limited to the above-described embodiments.

What is claimed is:

1. A non-volatile memory device, comprising:
a cell array including a first memory area and a second memory area;
a first page buffer circuit configured to write first data into the first memory area or sense the first data stored in the first memory area;
a second page buffer circuit configured to write second data into the second memory area or sense the second data stored in the second memory area;
a first data pad set disposed on a first side surface of the cell array and electrically connected to the first page buffer circuit; and
a second data pad set disposed on a second side surface of the cell array and electrically connected to the second page buffer circuit,
wherein the first data pad set and the second data pad set are electrically separated from each other.

2. The device of claim 1, further comprising:
a first data path circuit configured to transfer the first data between the first page buffer circuit and the first data pad set; and
a second data path circuit configured to transfer the second data between the second page buffer circuit and the second data pad set.

3. The device of claim 2, wherein the first side surface corresponds to a position among side surfaces of the cell array where a physical length of the first data path circuit is minimized.

4. The device of claim 3, wherein the second side surface corresponds to a position among side surfaces of the cell array where a physical length of the second data path circuit is minimized.

5. The device of claim 1, wherein at least one of a command pad set, an address pad set, and a clock signal pad set is located together on the first side surface with the first data pad set.

6. The device of claim 5, wherein a power pad or a reference voltage pad is located on the second side surface.

7. The device of claim 5, wherein the clock signal pad set includes a write enable signal pad or a read enable signal pad.

8. The device of claim 1, wherein the first data pad set or the second data pad set is formed in a pad-on-cell structure in which the first data pad set or the second data pad set overlaps the cell array area.

9. The device of claim 1, wherein the first memory area and the second memory area each correspond to a plane unit.

10. A non-volatile memory device, comprising:
a cell array including first to fourth memory areas;
first to fourth page buffer circuits respectively performing data input/output of the first to fourth memory areas;
a first data pad set located on a first side surface of the cell array and electrically connected to the first page buffer circuit or the second page buffer circuit;
a second data pad set located on a second side surface of the cell array and electrically connected to the third page buffer circuit or the fourth page buffer circuit;
a first data path circuit configured to transfer data between the first page buffer circuit or the second page buffer circuit and the first data pad set; and
a second data path circuit configured to transfer data between the third page buffer circuit or the fourth page buffer circuit and the second data pad set,
wherein the first data path circuit and the second data path circuit are electrically separated from each other.

11. The device of claim 10, wherein the first side surface and the second side surface correspond to positions where physical lengths of each of the first data path circuit and the second data path circuit are minimized.

12. The device of claim 10, wherein at least one of a command pad set, an address pad set, and a clock signal pad set is disposed together with the first data pad set on the first side surface.

13. The device of claim 11, wherein a power pad or a reference voltage pad is disposed on the second side surface together with the second data pad set.

14. The device of claim 11, wherein the first data pad set or the second data pad set is formed in a pad-on-cell structure that overlaps the cell array area.

15. The device of claim 10, wherein the first data path circuit comprises a first multiplexer configured to select either the first page buffer circuit or the second page buffer circuit to be connected to the first data pad set, and
wherein the second data path circuit comprises a second multiplexer configured to select either the third page buffer circuit or the fourth page buffer circuit to be connected to the second data pad set.

16. A non-volatile memory device, comprising:
a cell array including a first plane and a second plane;
a first page buffer circuit configured to input data into the first plane;
a second page buffer circuit configured to input data into the second plane;
a first data pad set disposed on a first side surface of the cell array and connected to the first page buffer circuit through a first data path circuit; and
a second data pad set disposed on a second side of the cell array at a different position from the first side surface and connected to the second page buffer circuit through a second data path circuit,
wherein the first data path circuit and the second data path circuit are electrically separated from each other.

17. The device of claim 16, wherein the first side surface corresponds to a position among side surfaces of the cell array where a physical length of the first data path circuit is minimized.

18. The device of claim 16, wherein the second side surface corresponds to a position among side surfaces of the cell array where a physical length of the second data path circuit is minimized.

19. The device of claim 18, wherein at least one set of a command pad set, an address pad set, and a clock signal pad set is disposed on the first side surface.

20. The device of claim 19, wherein a power pad or a reference voltage pad is disposed on the second side surface.
